(19) United States
(12) Patent Application Publication
(10) Pub. No.: US 2015/0094971 A1
(43) Pub. Date: Apr. 2, 2015

(54) Method for Determining a Maximum Available Constant Current of a Battery, Arrangement for Carrying Out said Method, Battery Combined with said Type of Arrangement and Motor Vehicle Comprising said Type of Battery

(71) Applicants: Robert Bosch GmbH, Stuttgart (DE); Samsung SDI Co., Ltd., Yongin-si, Gyeonggi-do (KR)

(72) Inventors: Andre Boehm, Kornwestheim (DE); Michael Rueger, Muenchen (DE); Anne Heubner, Stuttgart (DE); Stefan Wickert, Albershausen (DE)

(21) Appl. No.: 14/388,798

(22) PCT Filed: Feb. 6, 2013
(86) PCT No.: PCT/EP2013/052264

§ 371 Date: Sep. 26, 2014

(30) Foreign Application Priority Data
Mar. 28, 2012 (DE) 10 2012 204 957.6

(51) Int. Cl. G01R 31/36

(52) U.S. Cl. CPC G01R 31/3648
USPC 702/63

(57) ABSTRACT

A method for determining a maximum available first constant current of a battery over a first prediction period includes determining a maximum available second constant current for a second prediction period. The second prediction period occurs after the first prediction period. The method can further include limiting a first difference between the maximum available first constant current and the maximum available second constant current to one of less than or equal to a prescribed absolute value. The method can further include determining a maximum available first constant power of the battery over the first prediction period.

The present invention relates to a method for determining a maximum available constant current of a battery, an arrangement for carrying out such a method, a battery combined with such an arrangement and a motor vehicle comprising such a battery, it being possible for them to be used, in particular, to avoid undesirably large changes in the available current limit, and to provide a maximum applicable rate of change independently of the aging state of a battery.

### PRIOR ART

When batteries are being used, in particular in motor vehicles, the question arises concerning the constant current at which the battery can be discharged or under which it can be charged to a maximum extent over a specific prediction period without infringing limits for the operating parameters of the battery, in particular for the cell voltage. Two methods for determining such a maximum available constant current of a battery over a prediction period are known from the prior art.

In a first method known from the prior art, the maximum available constant current is determined iteratively with the aid of an equivalent circuit diagram model. In this case, the battery is simulated in each iteration over the entire prediction period on the assumption of a specific constant current. The iteration begins with a relatively low current value. If the voltage limit of the battery is not reached in the simulation, the current value for the next iteration is increased; if the voltage limit is reached, the iteration is ended. It is then possible to use as maximum available constant current the last current value at which the voltage limit of the battery was not reached in the simulation. It is disadvantageous of this method that the iteration and the simulation require a considerable computational outlay.

In a second method known from the prior art, the maximum available constant current is determined with the aid of characteristic diagrams as a function of temperature and charge status. It is disadvantageous of this method that the characteristic diagrams require a considerable outlay on storage. It is further disadvantageous that owing to the approximations inherent in the use of discretely stored characteristic diagrams it is necessary to provide a safety margin which leads to overdimensioning of the system.

It is also known to determine the maximum current by analytical calculation with the aid of an equivalent circuit diagram.

Furthermore, a method is known from DE 10 2008 004 368 A1 for determining a power available at a respective instant and/or electrical work and/or charge amount that can be drawn from a battery, in which a temporal charge amount profile is stored as charge prediction characteristic diagram for each combination of one of a multiplicity of temperature profiles with one of a multiplicity of power request profiles or one of a multiplicity of current request profiles.

A disadvantage of all the known methods results in the fact that no account is taken of an aging state of a battery. Likewise disadvantageous is the need to provide large amounts of memory for storing the characteristic diagrams.

### DISCLOSURE OF THE INVENTION

A particular advantage of the invention resides in the fact that changes in a current limit are kept within prescribable limits, particularly in the operation of electric or hybrid vehicles. This is achieved by virtue of the fact that in the case of the method according to the invention for determining a maximum available first constant current Iₗᵢₘ of a battery over a (first) prediction period T, account is taken of a maximum available second constant current for a later second prediction period. It turns out to be advantageous when the maximum available first constant current Iₗᵢₘ is determined in such a way that the difference, in particular the difference or the absolute value of the difference between the maximum available first constant current Iₗᵢₘ and the maximum available second constant current does not reach, or does not exceed a prescribable value. It turns out to be advantageous when account is taken of the charge status of the battery upon prescription of the value for limiting the difference between the maximum available first constant current Iₗᵢₘ and the maximum available second constant current.

In a preferred embodiment, the maximum power Pₗᵢₘ of the battery that can be called upon in the prediction period T is also determined in addition to the maximum available first constant current Iₗᵢₘ for the first prediction period T, the maximum change in the power being limited in accordance with the prediction period T. By way of example, it is provided herefor to determine the maximum available constant power Pₗᵢₘ over the prediction period T by determining the maximum available constant current Iₗᵢₘ of the battery for the prediction period T and averaging a voltage profile corresponding to the maximum available constant current Iₗᵢₘ over the prediction period T in order to determine an average voltage. The maximum available constant power Pₗᵢₘ over the prediction period T is then determined as a product of the maximum available first constant current Iₗᵢₘ for the first prediction period T and the average voltage.

A preferred embodiment provides that the maximum available first constant current Iₗᵢₘ for the first prediction period T is determined so that the difference, in particular the difference or the absolute value of the difference, between the first constant power Pₗᵢₘ, resulting from the maximum available first constant current Iₗᵢₘ, and a second constant power resulting from the maximum available 15 second constant current does not reach or does not exceed a prescribed absolute value.

It also turns out to be advantageous when, during the determination of the maximum available first constant current Iₗᵢₘ, account is taken of measuring tolerances, inertias and/or other faults, for example drifting, of the power electronics which are compensated by control algorithms.

A further preferred embodiment provides that the maximum available first constant current Iₗᵢₘ is determined by using an equivalent circuit diagram model.

One arrangement according to the invention has at least one chip and/or processor and is set up in such a way that it is possible to execute a method for determining a maximum available first constant current Iₗᵢₘ of a battery over a first prediction period T, account being taken during the determination of a maximum available second constant current for a later, second prediction period.

A further aspect of the invention relates to a battery which is combined with a module for determining a maximum available first constant current Iₗᵢₘ of the battery over a first prediction period T, the module being set up in such a way that it is possible to execute the determination of the maximum available first constant current Iₗᵢₘ, account being taken during the determination of a maximum available second constant current for a later, second prediction period. Preferably the battery is a lithium-ion battery or the battery comprises electrochemical cells which are designed as lithium-ion battery cells.

Another aspect of the invention relates to a motor vehicle comprising an electric drive motor for driving the motor vehicle and a battery in accordance with the aspect of the invention described in the previous paragraph which is, or can be, connected to the electric drive motor. However, the battery is not restricted to such an intended use, but can also be used in other electrical systems.

An important aspect of the invention consists in that calculating the current limits for two different instants, preferably for the start to and the end t₁ of the prediction period (also denoted as prediction horizon), results in the calculation of the slope of the resulting current limits produced when the calculated current limit is actually used. In a preferred embodiment of the invention, said slope is replaced by an applicable value, and the resulting equation is solved for the current limit for the present instant, for example for the current limit for t₀.

The resulting current limit is compared with at least one limit for at least one operating parameter of the battery, for example with a limit for the battery voltage Uₗᵢₘ, and limited.

In another preferred embodiment, it is provided that the determination of the maximum available constant current Iₗᵢₘ, of the battery is combined with a power prediction. This has the particular advantage that it is possible thereby to limit the maximum change in the predicted power.

A further advantage of the invention consists in that the battery can be provided with an application value which takes account of the aging state of the battery. The maximum rate of change of the permissible current can be prescribed and/or modified directly by the application value.

Since the power electronics of a vehicle are affected by measuring tolerances and inertia which are compensated by control algorithms, it is advantageous when the current limits to be observed remain within an applicable dynamics.

Owing to the fact that in accordance with the invention a change in the current limit ΔIₗᵢₘ is limited to a value ΔÎₗᵢₘ current limits are precluded from decreasing too rapidly because such a rapid change has a disadvantageous effect on the driving behavior (“bucking”). According to the invention, a maximum available constant current is therefore determined for a defined period, preferably 2 s or, with particular preference 10 s, which does not violate the prescribed voltage limits. The determined maximum available constant current can therefore be the current in the charging or discharging direction in this case.

A further advantage of the invention consists in that the maximum change in the maximum current after the defined period, in particular after the prediction period, is taken into account when calculating the maximum current at the present time.

It is, furthermore, to be regarded as advantageous that it is possible to undertake a limitation of the maximum change in a predicted power in a similar way.

Advantageous developments of the invention are specified in the subclaims and are described in the description.

### DRAWINGS

Exemplary embodiments of the invention are explained in more detail with the aid of the drawings and the following description. In the drawings:

FIG. 1 shows an equivalent circuit diagram for use in an exemplary embodiment of the method according to the invention,

FIG. 2 shows a schematic flow diagram of an exemplary embodiment of the method according to the invention, and

FIG. 3 shows two current diagrams for comparing the invention with a conventional determination of a maximum available constant current Iₗᵢₘ.

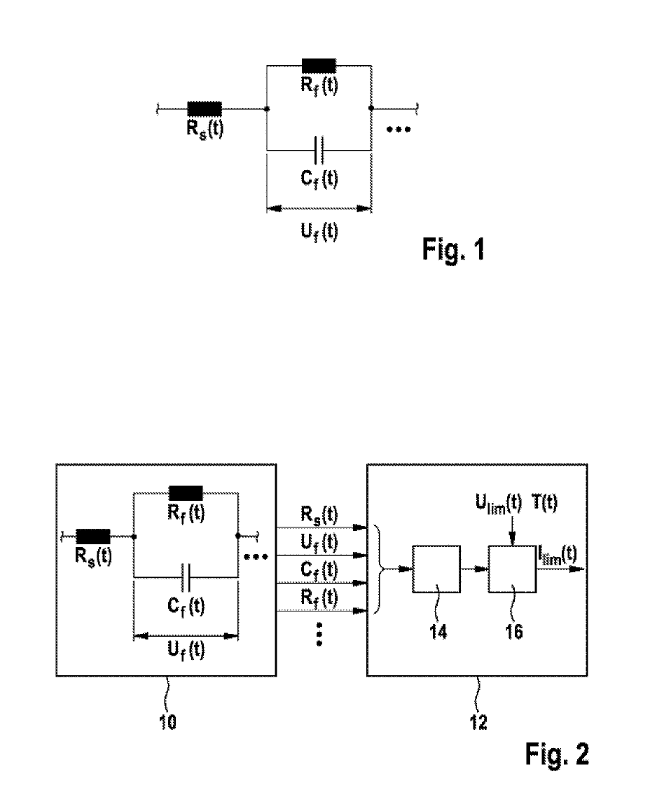

### EMBODIMENTS OF THE INVENTION

A calculation of the current prediction is described in more detail below without limitation of generality using an exemplary embodiment on the basis of an equivalent circuit diagram model with an ohmic resistor Rₛ and an RC element consisting of a parallel-connected ohmic resistor R_{f} and a capacitor C_{f}. An example of an equivalent circuit diagram suitable herefor is shown in FIG. 1. (The quantities are given in SI units.) The resistances Rₛ and R_{f}, the capacitance C_{f} and the voltage U_{f} present at the further element are taken to be time dependent in this case. It is also optionally possible to use an equivalent circuit diagram with any number of arbitrarily parameterized ohmic resistors and parallel connections with ohmic resistances and capacitances (RC elements).

With the aid of the equivalent circuit diagram model, a differential equation is set up to forecast the temporal development of the battery state, and then solved analytically using simplified assumptions. The cell voltage U_{cell} can be calculated at any instant using

U_{cell}(t)=U_{OCV}(t)+Uₛ(t)+U_{f}(t).

Here, U_{OCV}(t)=U_{OCV}(SOC(t),θ(t)) are the open circuit voltage, which depends on time via the charge status SOC(t) and the temperature θ(t); Uₛ(t)=Rₛ(SOC(t),θ(t))·I_{cell}(t) denotes the voltage drop across the resistance Rₛ, the resistance Rₛ being, in turn, dependent on time via the charge status SOC(t) and the temperature θ(t); I_{cell}(t) denotes the charging or discharging current at time t, and thus the current which flows in the equivalent circuit diagram model through the resistor Rₛ and the further element connected thereto in series; and U_{f}(t) denotes the voltage drop across the further element which is given by the solution of the differential equation

$${C}_{f} ( SOC ( t ) , θ ( t ) ) \frac{d }{d t} {U}_{f} ( t ) + \frac{{U}_{f} ( t )}{{R}_{f} ( SOC ( t ) , θ ( t ) )} = {I}_{cell} ( t )$$

valid in the equivalent circuit diagram model, for t>t₀ and initial value U_{f}(t₀)=U_{f}⁰ resistance R_{f} and the capacitance C_{f} also depending, in turn, upon time via the charge status SOC(t) and the temperature θ(t), and to denoting the beginning of the prediction period.

The following assumptions are made for the exemplary calculation:

The model parameters are independent of temperature θ and charge status SOC, that is to say it holds for the prediction period that Rₛ=const., R_{f}=const. and C_{f}=const.

The predicted maximum current is constant during the prediction period: Iₘₐₓ=const.

The present state U_{f}(t₀) is given for each initial point of the prediction to by using the model calculation in the battery state determination (BSD) (compare FIG. 1).

The change in the open circuit voltage owing to the change in the charge status of the battery is taken into account in a linear approximation, while the change in the open circuit voltage owing to the change in the temperature θ is, in turn, neglected:

$${U}_{OCV} ( t ) = {U}_{OCV} ( {t}_{0 } ) + Δ {U}_{OCV} \approx {U}_{OCV} ( {t}_{0} ) + Δ SOC ( t ) \frac{\partial {U}_{OCV}}{\partial SOC} ( {t}_{0} ) .$$

In this case, the result for the change in the charge status, specified as a percentage of the nominal charge (total capacity) chCap of the battery, from the current I_{cell} and time t is

$$Δ SOC ( t ) = {I}_{cell} \cdot ( t - {t}_{0 } ) \cdot \frac{100}{3600 \cdot chCap} ,$$

and the result for the slope is

$$\frac{\partial {U}_{OCV}}{\partial SOC} ( SOC ( {t}_{0} ) ) .$$

The slope term

$$\frac{\partial {U}_{OCV}}{\partial SOC} ( SOC ( {t}_{0} ) ) ,$$

the (partial) derivative of the open circuit voltage after the charge status is either calculated once and stored as a characteristic map, or it is calculated during operation from the characteristic map for U_{OCV}(SOC).

A change in charge status which is required to calculate the difference quotient is estimated via the previously calculated current limit Iₗᵢₘ(t₀−100 ms):

$$\frac{\partial {U}_{OCV}}{\partial SOC} ( SOC ( {t}_{0} ) ) \approx \frac{\begin{matrix}{U}_{OCV} ( SOC ( {t}_{0} ) + T / 2 \cdot {I}_{lim} ( {t}_{0} - 100 ms ) \cdot \frac{100}{chCap} ) - \\ {U}_{OCV} ( SOC ( {t}_{0} ) )\end{matrix}}{T / 2 \cdot {I}_{lim} ( {t}_{0} - 100 ms ) \cdot \frac{100}{chCap}}$$

Using the above assumptions and the time constant τ_{f}=C_{f}R_{f}, the result for the simplified differential equation is

$${\dot{U}}_{f} ( t ) = \frac{1}{{τ}_{f}} {U}_{f} ( t ) + \frac{1}{{C}_{f}} I ( t ) ∀ t > {t}_{0} , {U}_{f} ( {t}_{0} ) = {U}_{f}^{0} .$$

in which only the voltage U_{f}(t) depends on time. The solution is

$${U}_{f} ( t ) = {U}_{f}^{0} {e}^{- \frac{t - {t}_{0}}{{τ}_{f}}} + {I}_{cell} \cdot {R}_{f} \cdot ( 1 - {e}^{- \frac{t - {t}_{0}}{{τ}_{f}}} ) .$$

The total cell voltage at the instant t is therefore

$${U}_{cell} ( t ) = {U}_{OCV} ( {t}_{0} ) + {I}_{cell} \cdot ( t - {t}_{0} ) \cdot \frac{100}{chCap} \cdot \frac{\partial {U}_{OCV}}{\partial SOC} + {U}_{f}^{0} {e}^{- \frac{t - {t}_{0}}{{τ}_{f}}} + {I}_{cell} \cdot {R}_{s} + {I}_{cell} \cdot {R}_{f} \cdot ( 1 - {e}^{- \frac{t - {t}_{0}}{{τ}_{f}}} ) .$$

Solving for the constant current I_{cell} results in

$${I}_{cell} = \frac{{U}_{cell} ( t ) - {U}_{OCV } ( {t}_{0} ) - {U}_{f}^{0} {e}^{- \frac{t - {t}_{0}}{{τ}_{f}}}}{{R}_{s} + {R}_{f} \cdot ( 1 - {e}^{- \frac{t - {t}_{0}}{{τ}_{f}}} ) + ( t - {t}_{0} ) \cdot \frac{100}{chCap} \cdot \frac{\partial {U}_{OCV}}{\partial SOC}} .$$

Proceeding from the condition that the limit Uₗᵢₘ for the cell voltage U_{cell}(t) is to be observed at the end of the prediction period, at the time t=t₀+T, it is now possible to calculate the maximum available constant current Iₗᵢₘ by substituting said magnitudes:

$${I}_{lim} = \frac{{U}_{lim} - {U}_{OCV} ( {t}_{0} ) - {U}_{f}^{0} {e}^{- \frac{T}{{τ}_{f}}}}{{R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC}} . \qquad ( 1 )$$

In accordance with formula (1), the maximum currents at the respective instants result in the following way at two different instants to and t₁:

$${I}_{lim} ( {t}_{0} ) = \frac{{U}_{lim} - {U}_{OCV} ( {t}_{0} ) - {U}_{f}^{0} {e}^{- \frac{T}{{τ}_{f}}}}{{R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC} ( {t}_{0} )} and$$

$${I}_{lim} ( {t}_{1} = {t}_{0} + T ) = \frac{{U}_{lim} - {U}_{OCV} ( {t}_{1} ) - {U}_{f}^{1} {e}^{- \frac{T}{{τ}_{f}}}}{{R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC} ( {t}_{1} )} .$$

The change in the maximum currents

$$Δ {I}_{lim} = \frac{{I}_{lim} ( {t}_{1} ) - {I}_{lim} ( {t}_{0} )}{{t}_{1} - {t}_{0}}$$

is therefore

$$Δ {I}_{lim} = \frac{1}{T} [ \frac{{U}_{lim} - {U}_{OCV} ( {t}_{1} ) - {U}_{f}^{1} {e}^{- \frac{T}{{τ}_{f}}}}{{R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC} ( {t}_{1} )} - {I}_{lim} ( {t}_{0} ) ] . \qquad ( 2 )$$

The open circuit voltage U_{OCV}(t₁) at the instant t₁ can be described approximately as:

$${U}_{OCV} ( {t}_{1} ) \approx {U}_{OCV} ( {t}_{0} ) + {I}_{lim} ( {t}_{0} ) \cdot T \cdot \frac{100}{chCap} \cdot \frac{\partial {U}_{OCV}}{\partial SOC} ( {t}_{0} ) ,$$

and U_{f}¹ results from

$${U}_{f}^{1} = {U}_{f}^{0} {e}^{- \frac{T}{{τ}_{f}}} + {I}_{lim} ( {t}_{0} ) \cdot {R}_{f} \cdot ( 1 - {e}^{- \frac{T}{{τ}_{f}}} ) .$$

The t₁ terms in equation (2) can be eliminated with the aid of said expressions, the result being:

$$Δ {I}_{lim} = \frac{1}{T} [ \begin{matrix}\frac{{U}_{lim} - {U}_{OCV} ( {t}_{0} ) - {I}_{lim} ( {t}_{0} ) \cdot T \cdot \frac{100}{chCap} \cdot \frac{\partial {U}_{OCV}}{\partial SOC} ( {t}_{0} )}{{R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC} ( {t}_{1} )} - \\ \frac{{U}_{f}^{0} {e}^{- 2 \frac{T}{{τ}_{f}}} + {I}_{lim} ( {t}_{0} ) \cdot {R}_{f} \cdot ( 1 - {e}^{- \frac{T}{{τ}_{f}}} ) {e}^{- \frac{T}{{τ}_{f}}}}{{R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC} ( {t}_{1} )} - {I}_{lim} ( {t}_{0} )\end{matrix} ] .$$

Finally, solving for Iₗᵢₘ (t₀) yields the following equation for a current limit which reduces at the rate ΔÎₗᵢₘ:

$${I}_{lim} ( {t}_{0} ) == \frac{\begin{matrix}{U}_{lim} - {U}_{OCV} ( {t}_{0} ) - T \cdot \\ ( {R}_{s} + {R}_{f} \cdot ( 1 - {e}^{- \frac{T}{{τ}_{f}}} ) + T \cdot \frac{100}{chCap} \cdot \frac{\partial {U}_{OCV}}{\partial SOC} ( {t}_{1} ) ) \cdot Δ {\hat{I}}_{lim} - {U}_{f}^{0} {e}^{- 2 \frac{T}{{τ}_{f}}}\end{matrix}}{T \cdot \frac{100}{chCap} \cdot ( \frac{\partial {U}_{OCV}}{\partial SOC} ( {t}_{1} ) + \frac{\partial {U}_{OCV}}{\partial SOC} ( {t}_{0} ) ) + {R}_{f} \cdot ( 1 - {e}^{- 2 \frac{T}{{τ}_{f}}} ) + {R}_{s}}$$

An estimate of the profile of the characteristic line of the change in charge status for the prediction period is yielded as follows:

$$\frac{\partial {U}_{OCV}}{\partial SOC} ( SOC ( {t}_{1} = {t}_{0} + T ) ) \approx \approx \frac{{U}_{OCV} ( SOC ( {t}_{0} ) + T \cdot {I}_{lim} ( {t}_{0} - 100 ms ) \cdot \frac{100}{chCap} )}{T / 2 \cdot {I}_{lim} ( {t}_{0} - 100 ms ) \cdot \frac{100}{chCap}} - \frac{{U}_{OCV} ( SOC ( {t}_{0} ) + T / 2 \cdot {I}_{lim} ( {t}_{0} - 100 ms ) \cdot \frac{100}{chCap} )}{T / 2 \cdot {I}_{lim} ( {t}_{0} - 100 ms ) \cdot \frac{100}{chCap}} .$$

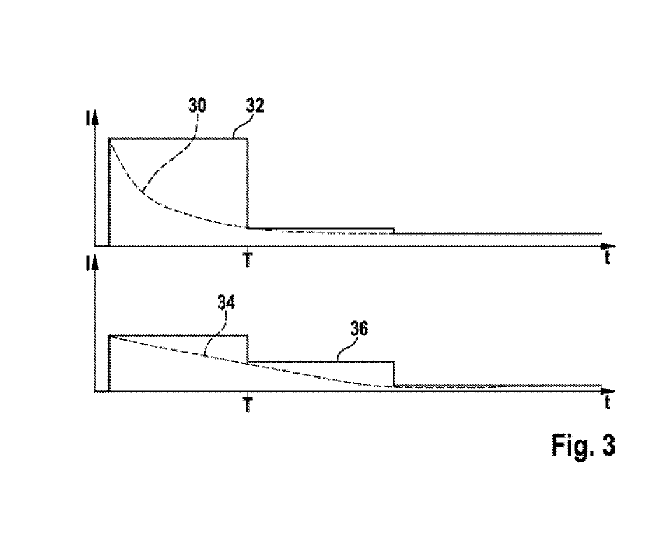

A dynamic calculation of the current limit without and with slope limitation is illustrated in FIG. 3.

While the upper diagram illustrates an analytically determined current limit 30 without restriction on a slope limit by means of a dashed curve, and a current 32 at the analytically determined current limit without restriction on a slope limit by means of an unbroken curve, the lower diagram represents an analytically determined current limit 34 with an inventive slope limitation ΔÎₗᵢₘ by means of a dashed curve and a current 36 at the analytically determined current limit with an inventive slope limit ΔÎₗᵢₘ by means of an unbroken curve. It is clearly to be seen that the change in the maximum current in accordance with the prediction period T is clearly limited by the invention in comparison with the prior art. Moreover, the invention enables the changes in the maximum current to be adjusted to one another in each case after the expiry of a plurality of prediction periods.

The invention is not limited in its embodiment to the preferred exemplary embodiments specified above. Rather, it is possible to conceive a number of variants which make use of the inventive method, the inventive device, the inventive battery and the inventive motor vehicle in the case of designs of fundamentally different type as well.

1. A method for determining a maximum available first constant current of a battery over a first prediction period, the method comprising:
during the determining of the maximum available first constant current, determining a maximum available second constant current for a second prediction period, wherein the second prediction period occurs after the first prediction period.

2. The method as claimed in claim 1, further comprising:
limiting a first difference between the maximum available first constant current and the maximum available second constant current to a first value less than or equal to a first prescribed absolute value.

3. The method as claimed in claim 1, further comprising:
determining a maximum available first constant power of the battery over the first prediction period includes:
determining the maximum available first constant current of the battery over the first prediction period;
determining an average voltage by averaging a voltage profile, corresponding to the maximum available first constant current, over the first prediction period; and
determining the maximum available first constant power of the battery based at least in part on the maximum available first constant current and the average voltage.

4. The method as claimed in claim 3, wherein the determining of the maximum available first constant current further comprises:
limiting a second difference between the first constant power resulting from the maximum available first constant current and a second constant power resulting from the maximum available second constant current to a second value than or equal to a second prescribed absolute value.

5. The method as claimed in claim 1, n wherein the determining of the maximum available first constant current, is based at least in part on measuring at least one of tolerances and inertias of power electronics.

6. The method as claimed in claim 2, wherein the first prescribed absolute value for the limiting of the first difference based at least in part on a charge status of the battery.

7. The method as claimed in claim 1, in wherein the determining of the maximum available first constant current is based at least in part on an equivalent circuit diagram model.

8. A system comprising:
at least one of a chip and a processor;
a module executed by the at least one of the chip and the processor and configured to determine a maximum available first constant current of a battery over a first prediction period by determining a maximum available second constant current for a second prediction period during the determination of the maximum available first constant current, wherein the second prediction period occurs after the first prediction period.

9. A battery, comprising:
a module configured to determine a maximum available first constant current of the battery over a first prediction period by determining a maximum available second constant current for a second prediction period during the determination of the maximum available first constant current, wherein the second prediction period occurs after the first prediction period.

10. The battery of claim 9, wherein the battery is comprised by a motor vehicle and the motor vehicle further comprises:
an electric drive motor for driving the motor vehicle, wherein the battery is connected to the electric drive motor.
